(19) United States
(12) Patent Application Publication
(10) Pub. No.: US 2008/0118769 A1
(43) Pub. Date: May 22, 2008

(54) Method of Manufacturing Thin Film, Method of Manufacturing P-Type Zinc Oxide Thin Film and Semiconductor Device

(75) Inventors: Masashi Kawasaki, Miyagi (JP); Akira Ohtomo, Miyagi (JP); Tomoaki Fukumura, Miyagi (JP); Atsushi Tsukazaki, Miyagi (JP); Makoto Ohtani, Miyagi (JP)

Correspondence Address: DICKSTEIN SHAPIRO LLP, 1825 EYE STREET NW, Washington, DC, 20006-5403, US

(73) Assignee: TOHOKU UNIVERSITY, SENDAI-SHI, MIYAGI (JP)

(21) Appl. No.: 10/588,283

(22) PCT Filed: Sep. 10, 2004
(86) PCT No.: PCT/JP04/13246

§ 371 Date: Jul. 23, 2007

(30) Foreign Application Priority Data
Feb. 6, 2004 (JP) 2004-031194

(51) Int. Cl. H01L 29/12; B29C 71/00; H05B 6/00

(52) U.S. Cl. 428/620; 264/235; 264/482

(57) ABSTRACT

There is provided a method of manufacturing a thin film, in which not only high crystallinity and surface flatness can be realized but also dopant doping can be performed at high concentration. The method includes a low temperature highly doped layer growing step of performing dopant doping while growing the thin film at a given first temperature; an annealing step of interrupting the growth of the thin film and annealing the thin film at a given second temperature higher than the first temperature; and a high temperature lowly doped layer growing step of growing the thin film at the second temperature.

### TECHNICAL FIELD

The present invention relates to a method of manufacturing a thin film. Especially, the present invention relates to a method of manufacturing a p-type zinc oxide thin film. The present invention also relates to a semiconductor device comprising a p-type zinc oxide thin film manufactured by such a method.

### BACKGROUND ART

As a new thin film material next to III-V nitride used in ultraviolet light emitting element and so on, zinc oxide is attracted. In such zinc oxide, high crystallinity and surface flatness are required and nitrogen doping at high concentration is also required in order to aim at p-type conduction. However, in order to obtain the high crystallinity and surface flatness, it is necessary to keep high growth temperature, and in order to perform doping at the high concentration, it is necessary to keep low growth temperature. It is known that the nitrogen is activated as an acceptor in the zinc oxide, and in order to perform the doping at the high concentration (about 100 ppm) during the growth of the zinc oxide thin film, however, it is necessary to decrease the growth temperature and thus the doping is usually performed at about 500° C. of the growth temperature.

Japanese Patent Application Opened No. 277,534/2000 by the present inventors et al discloses a semiconductor device in which crystallinity and electric property of a zinc oxide layer becomes close to those of a bulk single crystal by forming a zinc oxide thin film on a substrate using a pulse laser deposition, the substrate consisting of a material with a lattice constant highly matching that of zinc oxide. However, in this prior art, aiming at p-type conduction cannot be achieved because the crystallinity is not adequate.

Japanese Patent Application No. 335,898/2003 by the present inventors et al discloses that a single crystal thin film in which crystallinity, optical property and electric property of a zinc oxide layer are equal to those of the bulk is obtained by using annealed buffer layer, the zinc oxide layer being deposited on the buffer layer, the buffer layer being deposited on a substrate and the substrate consisting of a material with a lattice constant highly matching that of zinc oxide. However, in this prior art, also, aiming at p-type conduction cannot be achieved.

On the other hand, a resistor heater is traditionally used as means for heating the thin film. Japanese Patent Application Opened No. 87,223 by the present inventors et al discloses a heater using laser beam which can be used in oxidation atmosphere and can heat an insulating substrate effectively.

### DISCLOSURE OF THE INVENTION

The object of the present invention is to provide a method of manufacturing a thin film in which doping can be performed at high concentration while maintaining high crystallinity and surface flatness. The present invention also provides a method of manufacturing a p-type zinc oxide thin film in which the nitrogen doping can be performed while maintaining the high crystallinity and surface flatness. The present invention also provides a semiconductor device comprising a p-type zinc oxide film manufactured by such a method of manufacturing a p-type zinc oxide thin film.

There is provided one embodiment of a method of manufacturing a thin film comprising: a low temperature highly doped layer growing step of performing doping while growing the thin film at a given first temperature; an annealing step of interrupting the growth of the thin film and annealing the thin film at a given second temperature higher than the first temperature; and a high temperature lowly doped layer growing step of growing the thin film at the second temperature. [symbol] invention, a given number of the low temperature highly doped layer growing step, the annealing step and the high temperature lowly doped layer growing step are repeated.

There is provided further embodiment of a method of manufacturing a thin film comprising: a low temperature highly doped layer growing step of performing dopant doping while growing the thin film at a given first temperature; and an annealing step of interrupting the growth of the thin film and annealing the thin film at a given second temperature higher than the first temperature.

In further embodiment of the method according to the present invention, a given number of the low temperature highly doped layer growing step and the annealing step are repeated.

In further embodiment of the method according to the present invention, a heat-treatment from the first temperature to the second temperature is performed by radiation of a laser beam.

There is provided one embodiment of a method of manufacturing a p-type zinc oxide thin film comprising: a low temperature highly doped layer growing step of performing nitrogen doping while growing the zinc oxide thin film at a given first temperature; an annealing step of interrupting the growth of the zinc oxide thin film and annealing the zinc oxide thin film at a given second temperature higher than the first temperature; and a high temperature lowly doped layer growing step of growing the zinc oxide thin film at the second temperature.

In further embodiment of the method according to the present invention, a given number of the low temperature highly doped layer growing step, the annealing step and the high temperature lowly doped layer growing step are repeated.

In further embodiment of the method according to the present invention, the first temperature is about 300° C. and the second temperature is about 800° C.

In further embodiment of the method according to the present invention, a heat-treatment from the first temperature to the second temperature is performed by radiation of a laser beam.

There is provided one embodiment of a semiconductor device comprising the p-type zinc oxide thin film manufactured by the method according to the present invention.

In the further embodiment of the semiconductor device, the device is a light emitting device.

According to the present invention, the doping can be performed at high concentration while maintaining high crystallinity and surface flatness by the multi-stage annealing process during the growth of the thin film. With an apparatus of manufacturing a thin film using a computer-controlled laser as a heat source, the rapid increase and decrease of the temperature which is difficult for a prior resistor heater can be performed. According to the present invention, nitrogen doping can be performed at high concentration while maintaining the high crystallinity and surface flatness of the p-type zinc oxide thin film. According to the present invention, the p-type zinc oxide single crystal thin film can be obtained.

### BRIEF DESCRIPTION OF DRAWING

FIG. 1 is a diagram showing an apparatus of manufacturing the thin film which is preferable for carrying out the method of manufacturing the thin film according to the present invention.

FIG. 2 is a graph showing a sequence of the growth temperature and the thin film deposition in a first embodiment of the method of manufacturing the thin

[symbol]

FIG. 3 a graph showing a sequence of the growth temperature and the thin film deposition in a second embodiment of the method of manufacturing the thin film according to the present invention.

FIG. 4 is a graph showing the nitrogen concentration measured in the zinc oxide thin film manufactured by the method according to the present invention and that manufactured by the method according to prior art.

FIG. 5 is an atomic force microscopy image of the zinc oxide manufactured by the method according to the present invention and that manufactured by the method according to prior art.

FIG. 6 is a graph showing an electric property of the p-type zinc oxide thin film manufactured by the method according to the present invention.

FIG. 7 is a graph showing photo luminescent spectra of the p-type zinc oxide thin film manufactured by the method according to the present invention and that of the n-type zinc oxide thin film manufactured by the method according to prior art.

FIG. 8 is a graph showing the rectifying property of the pn junction of the zinc oxide manufactured by the method according to the present invention.

FIG. 9 is a graph showing the electro-luminescence spectra of the pn junction of the zinc oxide manufactured by the method according to the present invention.

FIG. 10 is a graph showing the injection current dependence of the electro-luminescence intensity of the pn junction of the zinc oxide manufactured by the method according to the present invention.

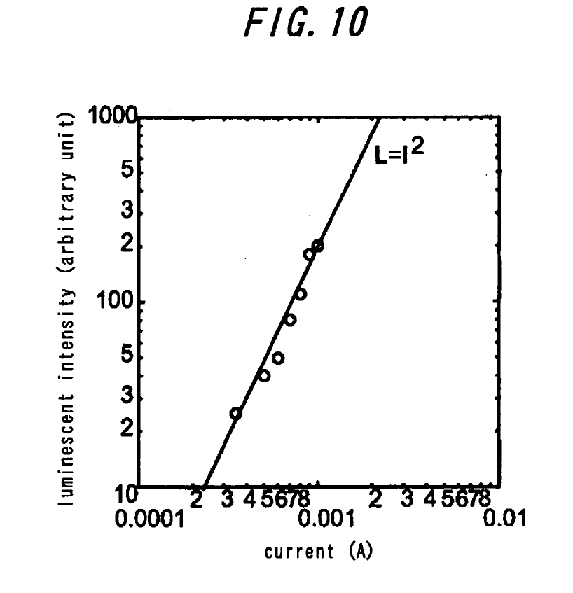

### BEST MODE FOR CARRYING OUT THE INVENTION

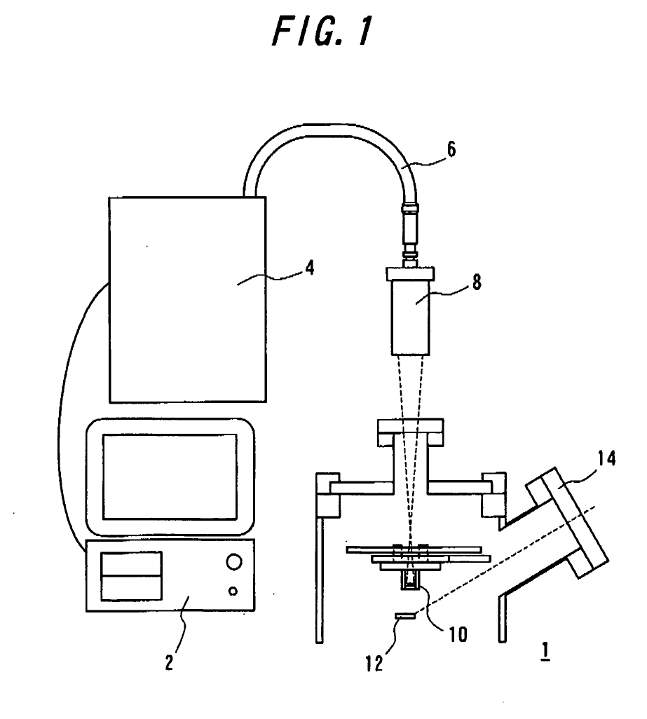

FIG. 1 is a diagram showing an apparatus of manufacturing the thin film which is preferable for carrying out the method of manufacturing the thin film according to the present invention. The apparatus 1 comprises a control computer 2, an Nd:YAG laser 4, an optical fiber 6, a lens 8, a substrate holder 10, a material target 12, and a viewport (an excimer laser guide port) 14. The apparatus 1 is generally a pulse laser deposition apparatus known from the skilled person, and forms a thin film on a substrate fixed on the substrate holder target 12 and performing an ablation. Further, similar to a laser heater in the above-mentioned Japanese Patent Application Opened No. 87,223/2000, the apparatus 1 heats the substrate holder 10 by guiding the Nd:YAG laser 4 though the optical fiber 6 and converging the Nd:YAG laser 4. In the substrate heating mechanism, it is not necessary to use the Nd:YAG laser and it is possible to obtain similar effect by using other optical means such as a semiconductor laser and an infrared lamp. The method of manufacturing the thin film according to the present invention carried out by using such an apparatus as an example will be explained hereinafter.

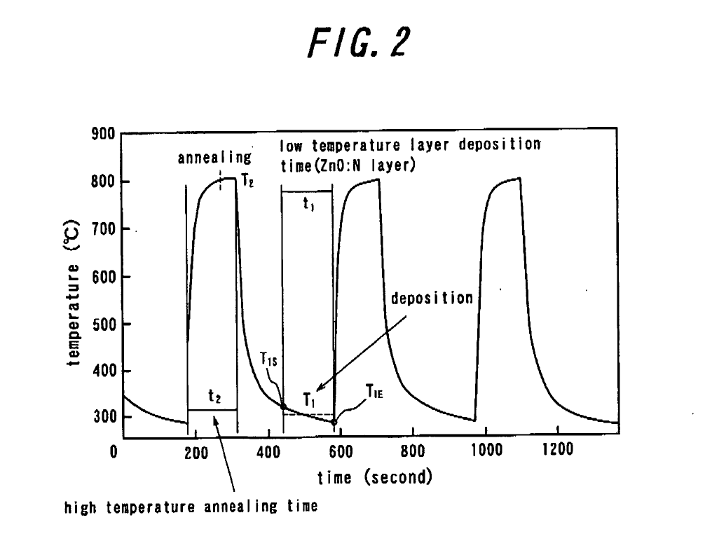

FIG. 2 is a graph showing a sequence of the growth temperature and the thin film deposition in a first embodiment of the method of manufacturing the thin film according to the present invention. First of all, as a first step, a low temperature highly doped layer is formed by performing doping while growing a thin film at a first temperature T₁ of about 300° C. during time t₁. The temperature T₁ is defined as an arithmetic mean of a first temperature and a last temperature at time t₁. (T₁=(T_{1S}+T_{1E})/2) It is advantageous to form such a low temperature highly doped layer in order to increase nitrogen concentration. Next, as a second step, the growth of the thin film is interrupted, and the temperature of the thin film is risen to a second temperature T₂ of about 800° C. by irradiating the Nd:YAG laser onto the substrate holder 10 with the control of the computer 2. The second temperature is maintained during time t₂ and the thin film is annealed. Such a high temperature annealing can reduce a crystal defect caused by the doping. After them, a given number of the first and second steps are repeated.

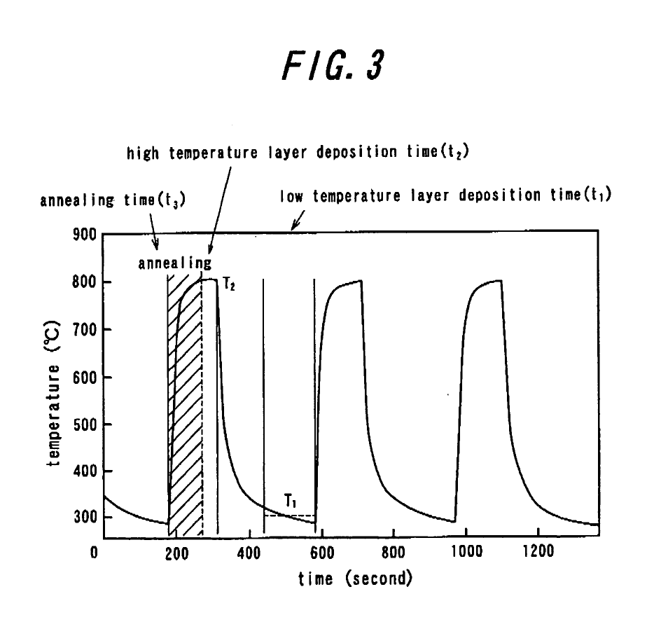

FIG. 3 a graph showing a sequence of the growth temperature and the thin film deposition in a second embodiment of the method of manufacturing the thin film according to the present invention. First of all, as a first step, similar to the first embodiment, a low temperature highly doped layer is formed by performing doping while growing a thin film at a first temperature T₁ of about 300° C. during time t₁. It is advantageous to form such a low temperature highly the growth of the thin film is interrupted, and the temperature of the thin film is increased to a second temperature T₂ of about 800° C. by irradiating the Nd:YAG laser onto the substrate holder 10 with the control of the computer 2. The second temperature is maintained during time t₂ and the thin film is annealed. Such a high temperature annealing can reduce a crystal defect result from the doping. Next, as a third step, a high temperature lowly doped layer is formed by growing the thin film during time t₃ while keeping the temperature T₂. Such a high temperature lowly doped layer changes a rough surface caused by the formation of the low temperature highly doped layer to a flat surface again at an atomic level. After them, a given number of the first, second and third steps are repeated. When a material of the thin film is zinc oxide and the dopant is nitrogen, it is possible to form a zinc oxide thin film in which nitrogen doping is performed at high concentration while maintaining the high crystallinity and surface flatness.

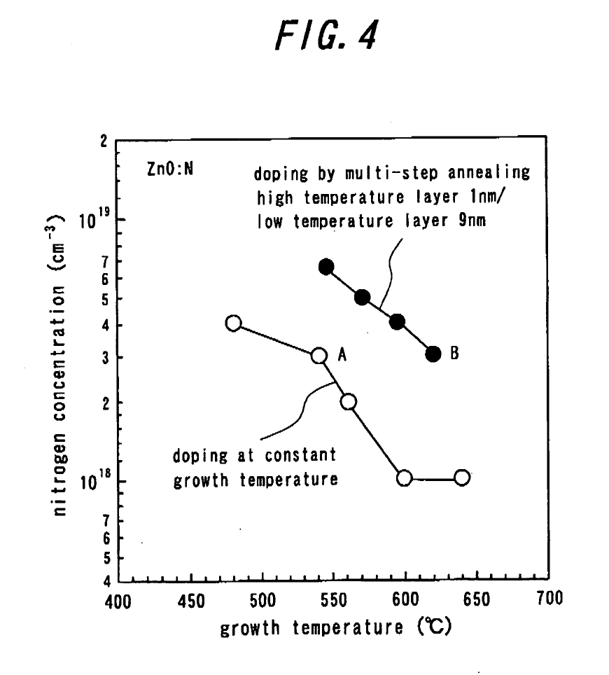

FIG. 4 is a graph showing the nitrogen concentration measured in the zinc oxide thin film manufactured by the method according to the present invention and that manufactured by the method according to prior art performing doping at a constant growth temperature. The zinc oxide thin film comprises the low temperature highly doped layer having a thickness of 9 nm and the high temperature lowly doped layer having a thickness of 1 nm, and is manufactured by the method comprising three steps of the second embodiment. In this graph, the growth temperature of the zinc oxide thin film manufactured by the present invention is T₁ in the temperature profile shown in FIG. 3. The zinc oxide thin film manufactured by the present invention has a higher average growth temperature than that of the zinc oxide thin film manufactured by the method according to prior art, however, the zinc oxide thin film manufactured by the present invention has high nitrogen concentration. This means that the nitrogen doped at low temperature is not vaporized at high temperature annealing and remains in the thin film.

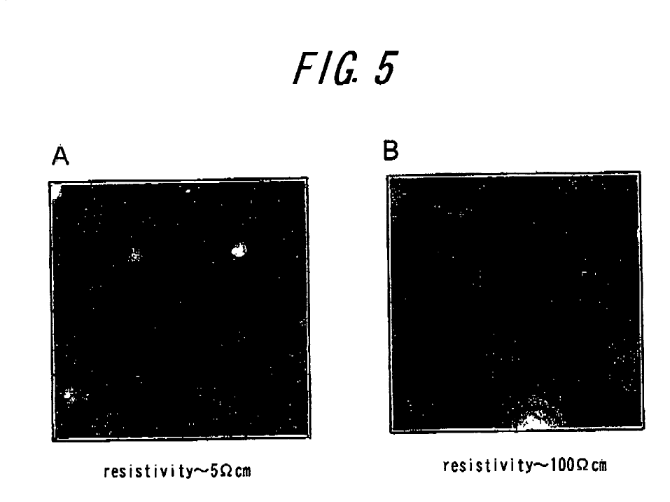

FIG. 5 is an atomic force microscopy image of the zinc oxide thin film manufactured by the method according to prior art on condition that the nitrogen condition in the method according to the present invention is equal to that in the method according to prior art, that is, on condition shown in A and B of FIG. 4. The resistivity of the thin film is represented under the microscopy image. The resistivity of the zinc oxide thin film manufactured by the method according to prior art is 50 Ωcm, the resistivity of the zinc oxide thin film manufactured by the method according to the present invention is 100 Ωcm and thus represents high resistivity. This suggests that the method according to the present invention annealing at high temperature is effective for the compensation of the crystal defect. Such an effect is obtained by the method comprising two steps of the first embodiment and is applied to other materials than the zinc oxide and the nitrogen.

Therefore, according to the present invention, as the nitrogen doping can be performed at high concentration while maintaining a flat growth surface at an atomic level, the p-type zinc oxide with high crystallinity can be formed.

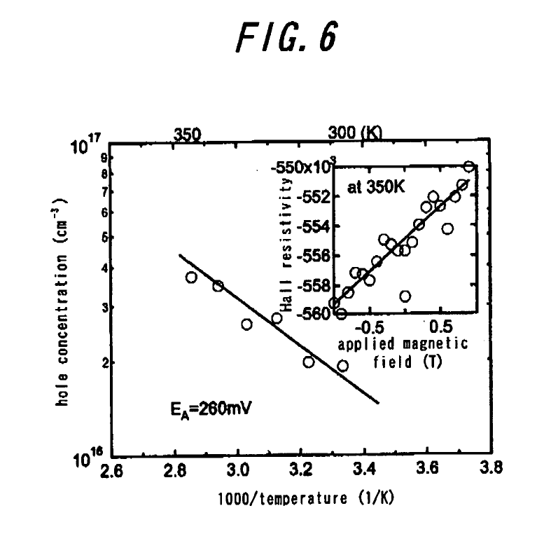

FIG. 6 is a graph showing an electric property of the p-type zinc oxide thin film manufactured by the method according to the present invention. An inserted figure represents a magnetic field dependency of Hall resistance measured at 350K, and a positive inclination shows that dominant carriers are holes. The carrier concentration calculated from the Hall resistance measured at 300 to 350 K is ˜10¹⁶ cm³, and the calculated activation energy of the hole is 260 meV. In the thin film manufactured by the method of manufacturing the zinc oxide thin film according to prior art, that is, the zinc oxide thin film manufactured on condition shown in FIG. 4A, the n-type conduction appears.

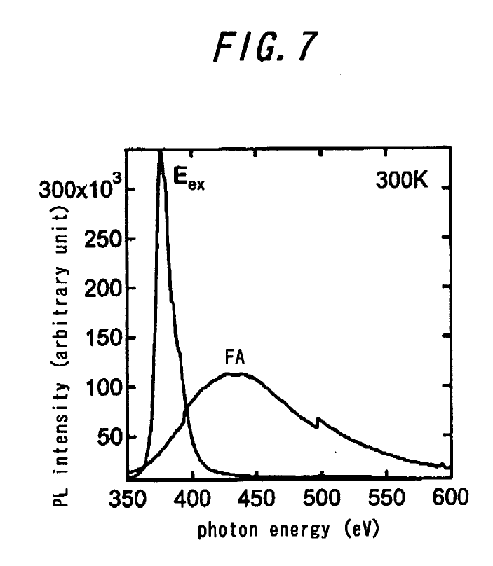

FIG. 7 is a graph showing photo luminescent spectra measured at room temperature of the p-type zinc oxide thin film manufactured by the method according to the present invention and that of the n-type zinc oxide thin film manufactured by the method according to prior art without nitrogen. The p-type zinc oxide thin film represents a remarkable donor-acceptor pair emission (shown [symbol] prior art represents free-exciton emission (shown as Eₑₓ in FIG. 7). An observation of the FA emission peak is one of phenomena involving the introduction of the hole.

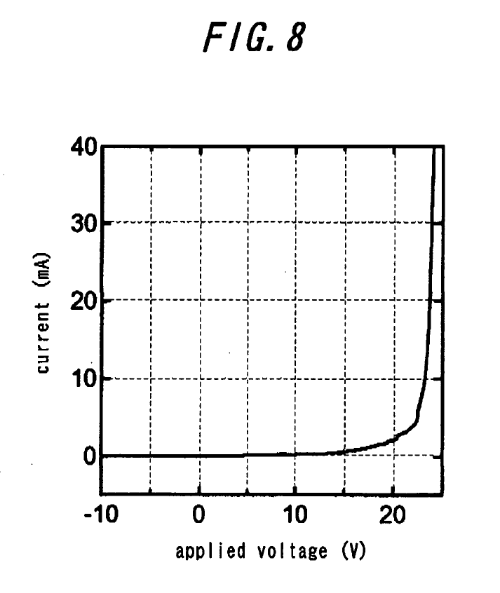

FIG. 8 is a graph showing the rectifying property of the pn junction of the zinc oxide thin film manufactured by the method according to the present invention and that of the n-type zinc oxide thin film manufactured by the method according to prior art without nitrogen, that is, FIG. 8 is a graph showing the rectifying property of a junction of the thin films shown in FIG. 7. This is one phenomenon shown by the pn junction and represents that the pn junction can be produced by the method of manufacturing the p-type zinc oxide thin film according to the present invention. The reason why the current increases at about 20V in the forward bias direction is that the sheet resistance of the n-type zinc oxide thin film at the lower side of the pn junction. When only the resistance at the pn junction plane is considered, the rising voltage at the forward bias reaches about the bandgap (3V). The reason why the increase of the voltage does not appear in the reverse bias direction is that the leakage current does not occur, which is often caused by a pin hole etc., because the surface of the p-type zinc oxide thin film is flat at an atomic level. Therefore, this result represents that the pn junction obtained by the present invention has high quality.

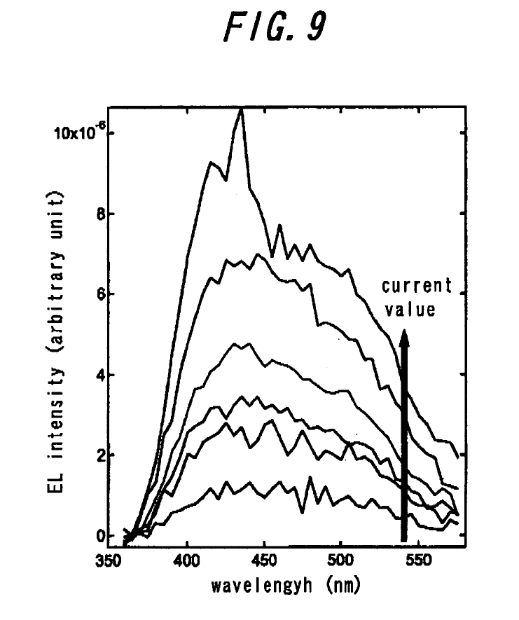

FIG. 9 is a graph showing the electro-luminescence spectra when the forward bias is applied to the pn junction of the zinc oxide shown in FIG. 8. With the increase of the current value, the increase of the wavelength range of 410 to 430 nm is remarkable. This is an emission caused by the band edge emission. Therefore, this result represents that the zinc oxide light emitting element is formed. The broad emission at small current is similar to the FA emission shown in FIG. 7. This suggests that the recombination of the electrons and the holes occurs on the p-type zinc oxide side, and this corresponds to the fact that the hole concentration of the p-type zinc oxide is lower than the electron concentration of the n-type zinc oxide. [symbol] intensity as a function of the current value when the forward bias is applied to the pn junction of the zinc oxide. The luminescent intensity increasing linearly for the square of the current value is similar to that of the light emitting element reported so far.

As described above, according to the method of manufacturing the p-type zinc oxide thin film according to the present invention, the p-type zinc oxide thin film can be actually manufactured, and not only the ultra violet light emitting element but also a zinc oxide bipolar transistor can be formed.

1. A method of manufacturing a thin film comprising:
a low temperature highly doped layer growing step of performing dopant doping while growing the thin film at a given first temperature;
an annealing step of interrupting the growth of the thin film and annealing the thin film at a given second temperature higher than said first temperature; and
a high temperature lowly doped layer growing step of growing the thin film at said second temperature.

2. The method according to claim 1, wherein a given number of said low temperature highly doped layer growing step, said annealing step and said high temperature lowly doped layer growing step are repeated.

3. A method of manufacturing a thin film comprising:
a low temperature highly doped layer growing step of performing dopant doping while growing the thin film at a given first temperature; and
an annealing step of interrupting the growth of the thin film and annealing the thin film at a given second temperature higher than said first temperature.

4. The method according to claim 3, wherein a given number of said low temperature highly doped layer growing step and said annealing step are repeated.

5. The method according to any one of claims 1 to 4, wherein a heat-treatment from said first temperature to said second temperature is performed by radiation of a laser beam.

6. A method of manufacturing a p-type zinc oxide thin film comprising:
a low temperature highly doped layer growing step of performing nitrogen doping while growing the zinc oxide thin film at a given first temperature;
an annealing step of interrupting the growth of the zinc oxide thin film and annealing the zinc oxide thin film at a given second temperature higher than said first temperature; and
a high temperature lowly doped layer growing step of growing the zinc oxide thin film at said second temperature.

7. The method according to claim 6, wherein a given number of said low temperature highly doped layer growing step, said annealing step and said high temperature lowly doped layer growing step are repeated.

8. The method according to claim 6 or 7, wherein said first temperature is about 300° C. and said second temperature is about 800° C.

9. The method according to any one of claim 6 or 7, wherein a heat-treatment from said first temperature to said second temperature is performed by radiation of a laser beam.

10. A semiconductor device comprising the p-type zinc oxide thin film manufactured by the method according to any one of claim 6 or 7.

11. The semiconductor device according to claim 10, said device is a light emitting device.

12-20. (canceled)

21. The method according to claim 8, wherein a heat-treatment from said first temperature to said second temperature is performed by radiation of a laser beam.

22. A semiconductor device comprising the p-type zinc oxide thin film manufactured by the method according to claim 8.
